(19) United States
(12) Patent Application Publication
(10) Pub. No.: US 2025/0349361 A1
(43) Pub. Date: Nov. 13, 2025

(54) MEMORY DEVICE HAVING WAFER-TO-WAFER BONDING STRUCTURE

(71) Applicant: SK hynix Inc., Icheon-si Gyeonggi-do (KR)

(72) Inventors: Jun Youp KIM, Icheon-si Gyeonggi-do (KR); Jin Ho KIM, Icheon-si Gyeonggi-do (KR)

(73) Assignee: SK hynix Inc., Icheon-si Gyeonggi-do (KR)

(21) Appl. No.: 18/895,774

(22) Filed: Sep. 25, 2024

(30) Foreign Application Priority Data
May 7, 2024 (KR) 10-2024-0059565

(51) Int. Cl. G11C 16/10; G11C 5/06; G11C 16/08; G11C 16/26; H01L 23/00; H10B 43/10; H10B 43/40

(52) U.S. Cl. CPC G11C 16/10; G11C 5/063; G11C 16/08; G11C 16/26; H01L 24/08; H10B 43/10; H10B 43/40; H01L 2224/08146

(57) ABSTRACT

A memory device includes a first wafer including a page buffer circuit and a data input/output circuit connected to the page buffer circuit; a second wafer having a first surface bonded to the first wafer and a second surface opposite to the first surface in a first direction and including a plurality of word lines, a memory cell array, and a plurality of bit lines connected to the page buffer circuit; and a third wafer bonded to the second surface of the second wafer and including a row decoder connected to the plurality of word lines and a voltage generator that provides an operating voltage to the row decoder.

### CROSS-REFERENCE TO RELATED APPLICATION

The present application claims priority under 35 U.S.C. § 119(a) to Korean Patent Application No. 10-2024-0059565 filed in the Korean Intellectual Property Office on May 7, 2024, which application is incorporated herein by reference in its entirety.

### BACKGROUND

### 1. Technical Field

Various embodiments generally relate to a semiconductor technology, including but not limited to a memory device having a wafer-to-wafer bonding structure.

### 2. Related Art

A memory device includes a memory cell array composed of memory cells that have different states depending on the stored data. The memory cells are accessed through word lines and bit lines. The memory device includes a peripheral circuit that is configured to control the word lines and the bit lines to access the memory cells and perform an operation requested from outside the memory device, for example, writing or reading data.

### SUMMARY

In an embodiment, a memory device may include: a first wafer including a page buffer circuit and a data input/output circuit connected to the page buffer circuit; a second wafer having a first surface bonded to the first wafer and a second surface opposite to the first surface in a first direction and including a plurality of word lines, a memory cell array, and a plurality of bit lines connected to the page buffer circuit; and a third wafer bonded to the second surface of the second wafer and including a row decoder connected to the plurality of word lines and a voltage generator that provides an operating voltage to the row decoder.

In an embodiment, a memory device may include: a first wafer including a page buffer circuit, a data input/output circuit and a plurality of first external connection pads; a second wafer having a first surface bonded to the first wafer and a second surface opposite to the first surface in a first direction and including a plurality of bit lines, a plurality of word lines, and a memory cell array; and a third wafer bonded to the second surface of the second wafer and including a row decoder, a voltage generator, and a plurality of second external connection pads.

In an embodiment, a memory device may include: a wafer having a first surface opposite to a second surface in a first direction; a first bonding pad disposed on the first surface; a second bonding pad disposed on the second surface; a gate stack disposed between the first surface and the second surface and including a plurality of gate electrode layers alternately stacked with a plurality of interlayer insulating layers in the first direction; a cell plug passing through the gate stack in the first direction; a bit line connected to the cell plug; and a word line contact extending to a gate electrode layer through the gate stack in the first direction and having a first end contacting the gate electrode layer and a second end opposite to the first end in the first direction, wherein the bit line is disposed between the first surface and the gate stack, and wherein the second end of the word line contact is disposed between the second surface and the gate stack.

In an embodiment, a method for manufacturing a memory device may include: forming, on a sacrificial substrate, a pre-stack comprising a plurality of sacrificial layers alternately stacked with a plurality of interlayer insulating layers; forming a cell plug passing through the pre-stack; forming, on the pre-stack, a first interconnection layer including a bit line connected to the cell plug and a first bonding pad connected to the bit line; forming a first peripheral wafer having a second interconnection layer including a second bonding pad; electrically connecting the first bonding pad to the second bonding pad by bonding the first interconnection layer to the second interconnection layer; removing the sacrificial substrate to expose a surface of the pre-stack; forming a word line contact that extends between the surface of the pre-stack and a sacrificial layer among the plurality of sacrificial layers; forming a gate stack by replacing the plurality of sacrificial layers with a plurality of gate electrode layers; forming, on the gate stack, a third interconnection layer including a third bonding pad connected to the word line contact; forming a second peripheral wafer having a fourth interconnection layer including a fourth bonding pad; and electrically connecting the fourth bonding pad to the third bonding pad by bonding the fourth interconnection layer to the third interconnection layer.

In an embodiment, a memory device may include a first wafer including a first peripheral circuit; a second wafer having a first surface bonded to the first wafer and a second surface and including a plurality of word lines, a memory cell array, and a plurality of bit lines connected to the first peripheral circuit through the first surface of the second wafer; and a third wafer bonded to the second surface of the second wafer and including a second peripheral circuit connected to the plurality of word lines through the second surface. The plurality of bit lines may be connected to the first peripheral circuit without passing through the third wafer. The plurality of word lines may be connected to the second peripheral circuit without passing through the first wafer.

### BRIEF DESCRIPTION OF THE DRAWINGS

FIG. 1 is a block diagram of a memory device based on an embodiment of the present disclosure.

FIG. 2 is a diagram illustrating a memory device based on an embodiment of the present disclosure.

FIG. 3 is a cross-sectional view of a memory device based on an embodiment of the present disclosure.

FIG. 4 is a cross-sectional view taken through a region including a first external connection pad in a second direction in accordance with the present disclosure.

FIG. 5 is a cross-sectional view taken through a region including a second external connection pad in the second direction in accordance with the present disclosure.

FIG. 6 is a cross-sectional view taken through a region including the first and second external connection pads in a first direction in accordance with the present disclosure.

FIG. 7 is a diagram illustrating a memory device based on an embodiment of the present disclosure.

FIG. 8 is a cross-sectional view illustrating a region including first external connection pads and second external connection pads in accordance with the present disclosure.

FIG. 9 is a plan view illustrating cell plugs, word line contacts, supports and slits of a memory device based on an embodiment of the present disclosure.

FIG. 10A to FIG. 10M are cross-sectional views illustrating the memory device based on an embodiment of the present disclosure according to a processing sequence.

### DETAILED DESCRIPTION

Embodiments of the disclosed technology are described in detail with reference to the accompanying drawings and present disclosure. The drawings are not necessarily drawn to scale. The cross-hatching throughout the figures illustrates corresponding or similar areas between the figures rather than indicating the materials associated with the areas.

Terms such as “first” and “second” are used to distinguish between various elements and do not imply size, order, priority, quantity, or importance of the elements. For example, a first element may be named as a second element in one example, and the second element may be named as a first element in another example.

When one element is identified as “connected” to another element, the elements may be connected directly or through an intervening element between the elements. When two elements are identified as “directly connected,” one element is directly connected to the other element without an intervening element between the two elements.

When time relative terms such as “after,” “before,” and the like are used to describe a relationship between two processes, the two processes or operations may be non-consecutive or non-sequential processes or operations, with or without intervening processes between the two processes or operations. When time relative terms are used in conjunction with “directly” or “immediately” for two processes, the two processes are performed consecutively or sequentially.

Terms such as “vertical,” “top,” “bottom,” “above,” “below,” “under,” “on,” “side,” “upper,” “lower,” “left,” “right,” “column,” “row,” “level,” and other terms implying relative spatial relationship or orientation are utilized only for the purpose of ease of description or reference to a drawing and are not otherwise limiting.

Various embodiments of the present disclosure are directed to a memory device having a wafer-to-wafer bonding structure.

According to the present disclosure, a connection structure that connects components included in a memory device may be simplified, and a space in which a peripheral circuit is disposed may be established or controlled.

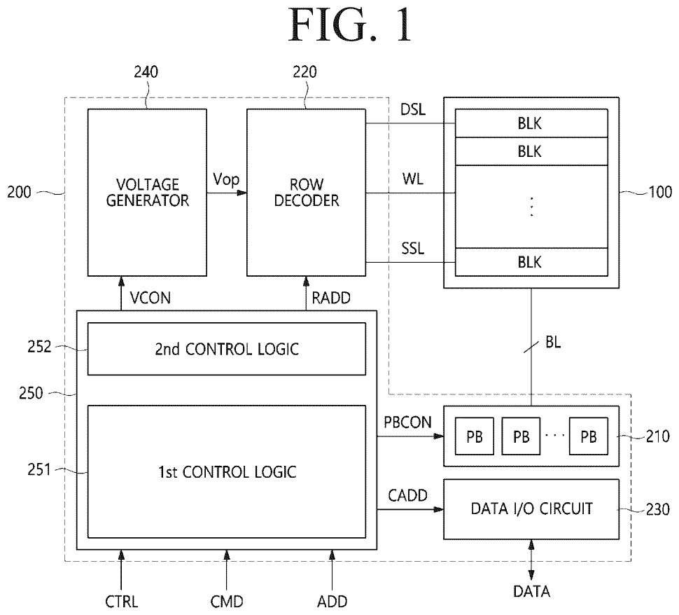

FIG. 1 is a block diagram of a memory device based on an embodiment of the present disclosure.

Referring to FIG. 1, the memory device includes a memory cell array 100 and a peripheral circuit 200. The peripheral circuit 200 includes a page buffer circuit 210, a row decoder 220, a data input/output circuit 230, a voltage generator 240, and a control logic 250. Although not illustrated, the peripheral circuit 200 may include additional peripheral circuits, for example, one or more of a reference voltage generation circuit, a temperature sensor, an electrostatic discharge (ESD) protection circuit, and a test circuit.

The memory cell array 100 includes a plurality of memory cells. The memory cell array 100 may be configured with a three-dimensional memory array of a type in which memory cells are stacked in a direction perpendicular to a substrate. The memory cell array 100 is connected to the page buffer circuit 210 through bit lines BL. The memory cell array 100 stores, during a program operation, data received through the page buffer circuit 210, and may transmit, in a read operation, stored data to the page buffer circuit 210. The memory cell array 100 is connected to the row decoder 220 through word lines WL and select lines DSL and SSL. The select lines DSL and SSL include a drain select line DSL and a source select line SSL.

The memory cell array 100 includes a plurality of memory blocks BLK. Each memory block BLK may be erasable. Each memory block BLK is connected to word lines WL, select lines DSL and SSL, and bit lines BL. Word lines WL and select lines DSL and SSL are connected to each memory block BLK. Bit lines BL may be connected in common to a plurality of memory blocks BLK.

The control logic 250 receives a control signal CTRL, a command CMD, and an address signal ADD from an external device, for example, a memory controller. The control logic 250 is configured to control overall operation of the memory device in response to the control signal CTRL and the command CMD. For example, in response to the command CMD, the control logic 250 controls the page buffer circuit 210, the row decoder 220, the data input/output circuit 230, and the voltage generator 240 such that an operation corresponding to the command CMD is performed, for example, a program operation, a read operation, or an erase operation.

The control logic 250 includes a first control logic 251 and a second control logic 252.

The first control logic 251 generates, in response to the command CMD, a page buffer control signal PBCON that controls the page buffer circuit 210. The first control logic 251 generates a column address CADD on the basis of the address signal ADD.

The second control logic 252 generates, in response to the command CMD, a voltage control signal VCON that controls the voltage generator 240. The second control logic 252 generates a signal that drives the row decoder 220, for example, a signal that determines the timing of a signal output by the row decoder 220. The second control logic 252 generates a row address RADD on the basis of the address signal ADD.

The page buffer circuit 210 includes a plurality of page buffers PB that are each connected to a corresponding bit line BL. The page buffer PB receives the page buffer control signal PBCON from the first control logic 251 and controls the bit line BL in response to the received page buffer control signal PBCCON. The page buffer PB senses the voltage potential of the bit line BL during the read operation of the memory cell array 100 and outputs, to the data input/output circuit 230, read data corresponding to the sensed voltage potential. For example, the page buffer PB temporarily stores data to be programmed into the memory cell array 100 or reads and stores data programmed to the memory cell array 100. The page buffer PB operates as a write driver or a sense amplifier depending on an operation mode. For example, the page buffer PB may operate as a sense amplifier in a read operation mode and as a write driver in a program operation mode.

Although not illustrated in FIG. 1, the page buffer circuit 210 includes a column decoder and receives the column address CADD from the first control logic 251.

The data input/output circuit 230 is connected to the page buffer circuit 210. During a program operation, the data input/output circuit 230 receives program data DATA from an external device and provides the program data DATA to the page buffer circuit 210 based on the column address CADD provided by the first control logic 251. During a read operation, the data input/output circuit 230 receives read data DATA stored in the page buffer circuit 210 based on the column address CADD provided by the first control logic 251 and outputs the read data DATA to an external device.

The voltage generator 240 receives the voltage control signal VCON from the second control logic 252 and generates various operating voltages Vop to be used during a program operation, a read operation, or an erase operation, in response to the received voltage control signal VCON. For example, the voltage generator 240 generates program voltages, pass voltages, read voltages, and erase voltages at various voltage levels in response to the voltage control signal VCON. The voltage generator 240 may include a charge pump and a regulator.

The row decoder 220 receives the row address RADD from the second control logic 252, and in response to the received row address RADD, selects any one of the memory blocks BLK included in the memory cell array 100. The row decoder 220 transmits the operating voltages Vop provided from the voltage generator 240 to the word lines WL and the select lines DSL and SSL connected to a memory block BLK selected from among the memory blocks BLK included in the memory cell array 100.

The peripheral circuit 200 is grouped into a first group that is associated with the bit lines BL and a second group that is associated with the word lines WL. The page buffer circuit 210, the data input/output circuit 230, and the first control logic 251 are included in the first group, and the row decoder 220, the voltage generator 240 and the second control logic 252 are included in the second group.

The memory device may have a multi-plane structure or a multi-bank structure. By increasing the quantity of planes and/or the quantity of banks of the memory device, improved high-speed operation and low power consumption may be achieved.

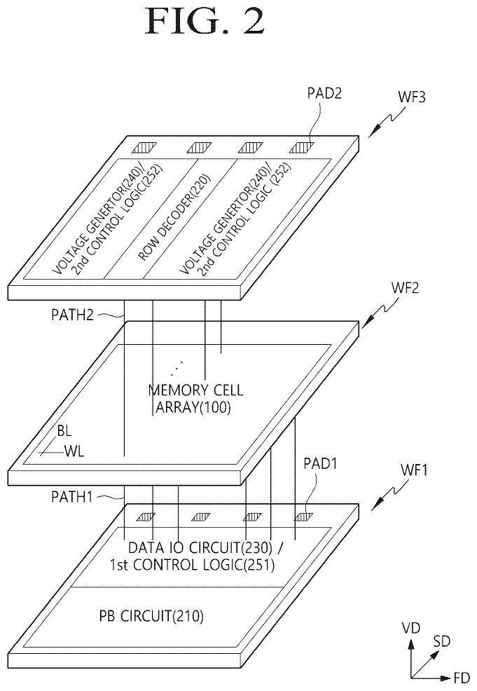

FIG. 2 is a diagram illustrating the memory device based on an embodiment of the present disclosure.

Referring to FIG. 2, the memory device includes a first wafer WF1, a second wafer WF2, and a third wafer WF3.

The second wafer WF2 is stacked on and bonded to the first wafer WF1 in a vertical direction VD also referred to as a third direction. The third wafer WF3 is stacked on and bonded to the second wafer WF2 in the vertical direction VD. The second wafer WF2 is bonded to the first wafer WF1 using a wafer-to-wafer bonding method. The third wafer WF3 may be bonded to the second wafer WF2 using a wafer-to-wafer bonding method.

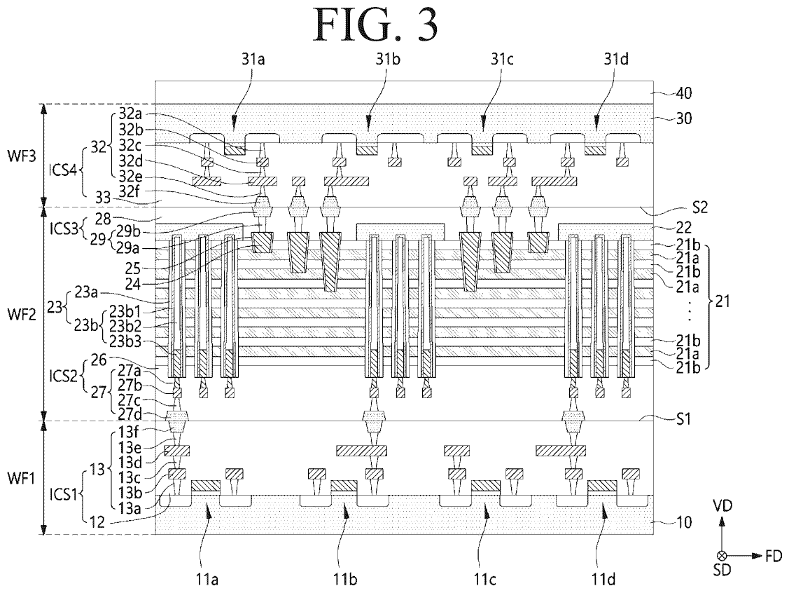

As described with reference to FIG. 3, the first wafer WF1 and the second wafer WF2 are electrically connected to each other through bonding pads that are disposed on the bonding surfaces of the first wafer WF1 and the second wafer WF2, such that when the first wafer WF1 is bonded to the second wafer WF2, the first wafer WF1 is electrically connected to the second wafer WF2. The second wafer WF2 is electrically connected to the third wafer WF3 through bonding pads that are disposed on the bonding surfaces of the second wafer WF2 and the third wafer WF3, such that when the second wafer WF2 is bonded to the third wafer WF3, the second wafer WF2 is electrically connected to the third wafer WF3.

FIG. 2 illustrates that the first wafer WF1 and the second wafer WF2 are separated from each other and the second wafer WF2 and the third wafer WF3 are separated from each other in an exploded view, although the top surface of the first wafer WF1 and the bottom surface of the second wafer WF2 are in contact with each other, and the top surface of the second wafer WF2 and the bottom surface of the third wafer WF3 are in contact with each other.

The memory cell array 100, the plurality of word lines WL and the plurality of bit lines BL are disposed on the second wafer WF2.

Circuits associated with the bit lines BL, such as the page buffer circuit 210 and the data input/output circuit 230, are disposed on the first wafer WF1. The first control logic 251 that controls the page buffer circuit 210 and the data input/output circuit 230 are disposed on the first wafer WF1.

Circuits associated with the word lines WL, for example, the row decoder 220 and the voltage generator 240, are disposed on the third wafer WF3. The second control logic 252 that controls the row decoder 220 and the voltage generator 240 are disposed on the third wafer WF3.

The data input/output circuit 230 is connected to the bit lines BL through first paths PATH1, such as conductive lines. Because the bit lines BL are disposed on the second wafer WF2 and the data input/output circuit 230 is disposed on the first wafer WF1, the first paths PATH1 are configured to extend between the second wafer WF2 and the first wafer WF1.

The row decoder 220 is connected to the word lines WL through second paths PATH2, such as conductive lines. Because the word lines WL are disposed on the second wafer WF2 and the row decoder 220 is disposed on the third wafer WF3, the second paths PATH2 are configured to extend between the second wafer WF2 and the third wafer WF3.

Because the first paths PATH1 and the second paths PATH2 are disposed on either the lower side or upper side, respectively, of the second wafer WF2, the quantity of bonding pads disposed on a single bonding surface and utilized to connect to paths is reduced when compared to an example where the first paths PATH1 and the second paths PATH2 are disposed on only one side of the second wafer WF2. When the quantity of bonding pads disposed on a single bonding surface is reduced, the gap between the bonding pads may be increased, and suppressing or preventing the occurrence of a bridge failure in which adjacent bonding pads are stuck together is more likely to be achieved.

The plurality of word lines WL extends in a first direction FD and is arranged in a second direction SD. The plurality of bit lines BL may alternatively extend in the second direction SD and may be arranged in the first direction FD. The first direction FD and the second direction SD are orthogonal to the vertical direction VD and intersect.

The page buffer circuit 210 is disposed in a region of the first wafer WF1 and extends in the first direction FD. The data input/output circuit 230 and the first control logic 251 are disposed in a region of the first wafer WF1 where the page buffer circuit 210 is not disposed. A section or the entirety of the page buffer circuit 210 is located below the memory cell array 100 in the vertical direction VD.

The row decoder 220 is disposed in a region of the third wafer WF3 and extends in the second direction SD. The voltage generator 240 and the second control logic 252 are disposed in a region of the third wafer WF3 where the row decoder 220 is not disposed. A section or the entirety of the row decoder 220 is located above the memory cell array 100 in the vertical direction VD. Although FIG. 2 illustrates an example where the row decoder 220 is aligned over a central section of the memory cell array 100, the present disclosure is not limited to this example. The row decoder 220 may be located above one or more edges of the memory cell array 100.

The memory cell array 100, the row decoder 220, and the page buffer circuit 210 may be at least partially aligned with each other in the vertical direction VD.

Because the page buffer circuit 210 and the memory cell array 100 are at least partially aligned in the vertical direction VD, and the page buffer circuit 210 is disposed in the region that extends in the first direction FD and the row decoder 220 extends above the memory cell array 100 in the vertical direction VD and is disposed in a region that extends in the second direction SD, the region where the page buffer circuit 210 is disposed and the region where the row decoder 220 is disposed are at least partially aligned in the vertical direction. The memory cell array 100, the row decoder 220 and the page buffer circuit 210 each include regions that are commonly aligned with each other in the vertical direction VD.

The first wafer WF1 includes a plurality of first external connection pads PAD1, and the third wafer WF3 includes a plurality of second external connection pads PAD2.

The first external connection pads PAD1 are arranged adjacent to an edge of the first wafer WF1 in the first direction FD. The second external connection pads PAD2 are arranged adjacent to an edge of the third wafer WF3 in the first direction FD. As illustrated in FIG. 2, a region where the first external connection pads PAD1 are disposed is located in the vertical direction VD below a region where the second external connection pads PAD2 are disposed, although the present disclosure is not limited to this example.

The first external connection pads PAD1 include a data pad, a power pad, and a ground pad in this example. The first external connection pads PAD1 may additionally include a command pad, an address pad, and a control signal pad.

The second external connection pads PAD2 include an analog signal pad, a power pad, and a ground pad in this example. For convenience in explanation, the power pad and the ground pad included in the first external connection pads PAD1 are referred to as a first power pad and a first ground pad, respectively, and the power pad and the ground pad included in the second external connection pads PAD2 are referred to as a second power pad and a second ground pad, respectively.

The memory device transmits and receives data through the data pad to and from an external device. The memory device receives a power supply voltage through the power pads from outside the memory device and receives a ground voltage through the ground pads from outside the memory device. The memory device receives one or more commands through the command pad from an external device, receives one or more addresses through the address pad from an external device, and receives one or more control signals through the control signal pad from an external device.

The control signal pad includes, for example, an address latch enable signal (ALE) pad, a command latch enable signal (CLE) pad, a ready/busy signal (RB) pad, a write enable signal (WE) pad, a write protect signal (WP) pad, a chip enable signal (CE) pad, a calibration signal (ZQ) pad, a data bus inversion signal (DBI) pad, a data strobe signal (DQS) pad, or a read enable signal (RE) pad.

The first external connection pads PAD1 may further include an option pad. The option pad may include a DDP option pad (SD SEL), a QDP option pad (QD SEL), an INT pad, or an FB pad. An enable signal is input through the DDP option pad (SD SEL) to identify a DDP (dual die package) option where two chips are allocated to or disposed in one chip package. A signal is input through the QDP option pad (QD SEL) to identify a QDP (quad die package) option where four chips are allocated to or disposed in one chip package. A signal is input through the FB pad to distinguish the chips allocated to one chip enable signal in the DDP option or the QDP option. When multiple chip enable pads are present on a single chip, a signal is input through the INT pad to distinguish between the multiple chip enable signal (CE) pads existing in the single chip.

The data pad is connected to the data input/output circuit 230 through a data transmission path in the first wafer WF1. The data transmission path include wiring, such as a conductor, and a circuit. The data input/output circuit 230 is connected to the data pad through the data transmission path to exchange data with an external device.

Because the data pad and the data input/output circuit 230 are disposed on the first wafer WF1, the data transmission path that connects the data pad and the data input/output circuit 230 is configured on the first wafer WF1. Because the data transmission path is configured on the first wafer WF1 without passing through another wafer, the data transmission path has a shorter length than a transmission path that passes through another wafer. The load of the data transmission path may be reduced and achieve data integrity goals. Because the data transmission path is configured without using a through wiring passing through the second wafer WF2, the quantity of through wirings may be reduced.

The first power pad is connected to circuits in the first wafer WF1 through a first power transmission path on the first wafer WF1. The first ground pad is connected to the circuits in the first wafer WF1 through a first ground line on the first wafer WF1. The second power pad is connected to circuits in the third wafer WF3 through a second power transmission path on the third wafer WF3. The second ground pad is connected to the circuits in the third wafer WF3 through a second ground line on the third wafer WF3.

The circuits on the first wafer WF1 are connected to the first power pad through the first power transmission path to be provided with a power supply voltage received through the first power pad from outside the memory device. The circuits on the first wafer WF1 are connected to the first ground pad through the first ground line to be provided with a ground voltage received through the first ground pad from outside the memory device. The circuits on the third wafer WF3 are connected to the second power pad and the second ground pad through the second power transmission path and the second ground line, respectively, and are provided with a power supply voltage and a ground voltage received through the second power pad and the second ground pad, respectively, from outside the memory device.

Because the first power pad that receives the power supply voltage and the first ground pad that receives the ground voltage for the first wafer WF1 are disposed on the first wafer WF1, the first power transmission path and the first ground line are configured on the first wafer WF1. Because the first power transmission path and the first ground line are configured on the first wafer WF1 without passing through another wafer, the first power transmission path and the first ground line have shorter lengths than a power transmission path and a ground line that pass through another wafer. Because the first power transmission path and the first ground line are configured without using through wirings that pass through the second wafer WF2, the quantity of through wirings may be reduced.

Because the second power pad that receives the power supply voltage and the second ground pad that receives the ground voltage for the circuits of the third wafer WF3 are disposed on the third wafer WF3, the second power transmission path and the second ground line are configured on the third wafer WF3. Because the second power transmission path and the second ground line are configured on the third wafer WF3 without passing through another wafer, the second power transmission path and the second ground line have shorter lengths than a power transmission path and a ground line that pass through another wafer. Because the second power transmission path and the second ground line are configured without using through wirings that pass through the second wafer WF2, the quantity of through wirings may be reduced.

According to an embodiment of the present disclosure, because the circuits associated with the bit lines BL and the circuits associated with the word lines WL are separated and disposed on the first wafer WF1 and the third wafer WF3, respectively, and because the first wafer WF1 and the third wafer WF3 are each bonded to one of the bottom surface and the top surface of the second wafer WF2 in which the memory cell array 100 is disposed, the first paths PATH1 that connect the bit lines BL and the page buffer circuit 210 are separated and disposed on a different side of the second wafer WF2 than the side of the second wafer WF2 on which the second paths PATH2 that connect the word lines WL and the row decoder 220 are disposed. Accordingly, a connection structure that connects components included in the memory device may be simplified, and space on which peripheral circuits are disposed may be increased. The additional space may be used to implement a row decoder, to increase the capacity of the memory device, to increase the quantity of banks in the memory device, or to increase the quantity of planes in the memory device, thereby resulting in improvements to high-speed operation and low power consumption of the memory device.

The structure of the memory device is described in detail with reference to FIG. 3.

FIG. 3 is a cross-sectional view of the memory device based on an embodiment of the present disclosure.

Referring to FIG. 3, the first wafer WF1 includes a first substrate 10, a plurality of first circuit elements 11a, 11b, 11c and 11d that are formed on the first substrate 10, and a first interconnection layer ICS1.

The first circuit elements 11a, 11b, 11c and 11d are used to configure the page buffer circuit 210, the data input/output circuit 230, and the first control logic 251.

The first interconnection layer ICS1 includes a first insulating layer 12 and a plurality of first connection structures 13. The first connection structures 13 include a first metal layer 13b, a second metal layer 13d, a first bonding pad 13f, and first vias 13a, 13c and 13e. The first insulating layer 12 is disposed on the first substrate 10. The first insulating layer 12 covers the first circuit elements 11a, 11b, 11c and 11d and the first connection structures 13 on the first substrate 10. In the example of FIG. 3, the first connection structure 13 includes two metal layers. The present disclosure is not limited to this example, and the first connection structure 13 may include at least one metal layer.

The top surfaces of the first bonding pads 13f are exposed adjacent to the top surface of the first insulating layer 12 prior to bonding the first wafer WF1 and the second wafer WF2. The top surface of the first bonding pad 13f is disposed on the same plane as the top surface of the first insulating layer 12.

The second wafer WF2 includes a gate stack 21, a source plate 22, a plurality of cell plugs 23, a plurality of word line contacts 24, a second interconnection layer ICS2, and a third interconnection layer ICS3.

The second wafer WF2 includes a first surface S1 and a second surface S2 that face in opposite directions in the vertical direction VD. The first surface S1 of the second wafer WF2 may be bonded to the first wafer WF1, and the second surface S2 of the second wafer WF2 may be bonded to the third wafer WF3.

The gate stack 21 is disposed between the first surface S1 and the second surface S2. The gate stack 21 includes a plurality of gate electrode layers 21a alternately stacked with a plurality of interlayer insulating layers 21b in the vertical direction VD. The gate electrode layers 21a include word lines. The gate electrode layers 21a further include at least one source select line and at least one drain select line.

The source plate 22 is disposed on one surface of the gate stack 21 nearer to the second surface S2 than to the first surface S1. The source plate 22 may include a doped semiconductor.

The cell plugs 23 extend into the source plate 22 and through the gate stack 21 in the vertical direction VD.

The cell plugs 23 are formed before bonding the second wafer WF2 to the first wafer WF1. The cell plugs 23 may have a reverse tapered shape with a width, in the first direction FD, that increases closer to the first wafer WF1.

The cell plug 23 includes a memory pattern 23a and a channel structure 23b. Although not illustrated, the memory pattern 23a includes a tunnel insulating layer, a data storage layer, and a first blocking insulating layer. The tunnel insulating layer extends along the outer surface of the channel structure 23b and includes an insulating material capable of charge tunneling. The data storage layer extends along the outer surface of the tunnel insulating layer, with the tunnel insulating layer interposed between the data storage layer and the channel structure 23b. The data storage layer may include a material capable of storing data that is changed, for example, using Fowler-Nordheim tunneling. For example, the data storage layer may include nitride capable of charge trapping, but is not limited to such a material. The data storage layer may include a phase change material, nanodots, and so forth. The first blocking insulating layer extends along the outer surface of the data storage layer, with the tunnel insulating layer and the data storage layer interposed between the first blocking insulating layer and the channel structure 23b. The first blocking insulating layer may include an insulating material capable of blocking the movement of charges.

The channel structure 23b includes a channel layer 23b1, a core pillar 23b2, and a capping pattern 23b3. The channel layer 23b1 is used as the channel of a memory cell string. The channel layer 23b1 is disposed on an inner surface of the memory pattern 23a and may be formed of a semiconductor material. For example, the channel layer 23b1 may include silicon. The core pillar 23b2 and the capping pattern 23b3 fill the central section of the channel structure 23b. The core pillar 23b2 may include oxide. The capping pattern 23b3 is disposed on the core pillar 23b2 and includes a sidewall surrounded by an end of the channel layer 23b1. The capping pattern 23b3 may include a doped semiconductor that includes at least one of an n-type impurity and a p-type impurity.

The core pillar 23b2 includes a protrusion that protrudes or extends above the gate stack 21. The channel layer 23b1 surrounds the protrusion of the core pillar 23b2. The source plate 22 surrounds the channel layer 23b1 that surrounds the protrusion of the core pillar 23b2 and contacts the channel layer 23b1 that surrounds the protrusion of the core pillar 23b2.

Each of the plurality of word line contacts 24 corresponds to one of the gate electrode layers 21a and extends to a corresponding gate electrode layer 21a by extending through the gate stack 21 in the vertical direction VD. An insulating sidewall 25 surrounds the outer side surface of the word line contact 24.

The word line contact 24 includes a first end that contacts a corresponding gate electrode layer 21a and a second end that is opposite to the first end. The first end of the word line contact 24 is disposed in the corresponding gate electrode layer 21a, and the second end is disposed between the gate stack 21 and the third wafer WF3.

The word line contacts 24 may be formed after bonding the second wafer WF2 to the first wafer WF1. The word line contacts 24 may have a tapered shape with a width, in the first direction FD, that decreases closer to the first wafer WF1.

The second interconnection layer ICS2 includes a second insulating layer 26 and a plurality of second connection structures 27. The second connection structures 27 include a third metal layer 27b, a second bonding pad 27d, and second vias 27a and 27c.

The third metal layer 27b includes a bit line. The third metal layer 27b is referred to as a bit line. In the example of FIG. 3, the second connection structure 27 includes one metal layer. The present disclosure is not limited to this example, and the second connection structure 27 may include at least two metal layers.

The second insulating layer 26 covers the second connection structures 27 and the bottom surface of the gate stack 21 that faces the first wafer WF1. The bottom surfaces of the second bonding pads 27d are exposed adjacent to the bottom surface of the second insulating layer 26 prior to bonding the first wafer WF1 and the second wafer WF2. The bottom surfaces of the second bonding pads 27d are disposed on the same plane as the bottom surface of the second insulating layer 26. The bottom surfaces of the second bonding pads 27d and the bottom surface of the second insulating layer 26 may configure the first surface S1 of the second wafer WF2.

The second interconnection layer ICS2 is bonded to the first interconnection layer ICS1. The bottom surface of the second insulating layer 26 of the second interconnection layer ICS2 is bonded to the top surface of the first insulating layer 12 of the first interconnection layer ICS1, and the second bonding pads 27d of the second interconnection layer ICS2 are bonded to corresponding first bonding pads 13f of the first interconnection layer ICS1. Thus, the first wafer WF1 and the second wafer WF2 are bonded to each other.

The third interconnection layer ICS3 includes a third insulating layer 28 and a plurality of third connection structures 29. The third connection structures 29 are connected to the word line contacts 24. The third connection structure 29 include a third bonding pad 29b and a third via 29a.

The third insulating layer 28 covers the source plate 22, the word line contacts 24, the third connection structures 29, and the top surface of the gate stack 21 that faces the third wafer WF3. The top surfaces of the third bonding pads 29b are exposed adjacent to the top surface of the third insulating layer 28 prior to bonding the second wafer WF2 and the third wafer WF3. The top surfaces of the third bonding pads 29b are located on the same plane as the top surface of the third insulating layer 28. The top surfaces of the third bonding pads 29b and the top surface of the third insulating layer 28 encompass the second surface S2 of the second wafer WF2.

The third wafer WF3 includes a second substrate 30, a plurality of second circuit elements 31a, 31b, 31c and 31d formed on the bottom surface of the second substrate 30, and a fourth interconnection layer ICS4.

The second circuit elements 31a, 31b, 31c, and 31d are used to configure the row decoder 220, the voltage generator 240, and the second control logic 252.

The fourth interconnection layer ICS4 includes a plurality of fourth connection structures 32 and a fourth insulating layer 33. The fourth connection structures 32 include fourth bonding pad 32f, a fourth metal layer 32d, a fifth metal layer 32b, and fourth vias 32a, 32c, and 32e. In the example of FIG. 3, the fourth connection structure 32 includes two metal layers, but the present disclosure is not limited to this example.

The fourth insulating layer 33 covers the bottom surface of the second substrate 30, the second circuit elements 31a, 31b, 31c, and 31d and the fourth connection structures 32. The bottom surfaces of the fourth bonding pads 32f are exposed adjacent to the bottom surface of the fourth insulating layer 33. The bottom surfaces of the fourth bonding pads 32f are located on the same plane as the bottom surface of the fourth insulating layer 33.

The fourth interconnection layer ICS42 is bonded to the third interconnection layer ICS3. The bottom surface of the fourth insulating layer 33 of the fourth interconnection layer ICS4 is bonded to the top surface of the third insulating layer 28 of the third interconnection layer ICS3, and the fourth bonding pads 32f of the fourth interconnection layer ICS4 are bonded to corresponding third bonding pads 29b of the third interconnection layer ICS3. Thus, the second wafer WF2 and the third wafer WF3 are bonded to each other.

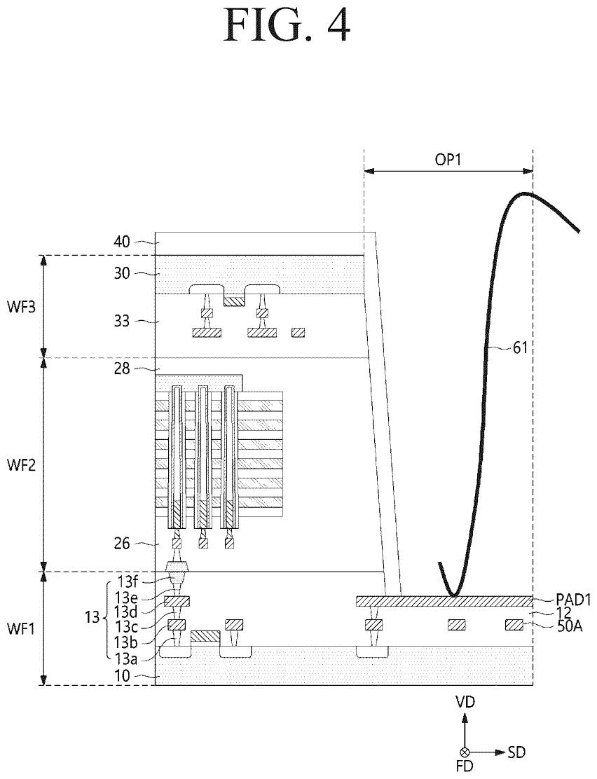

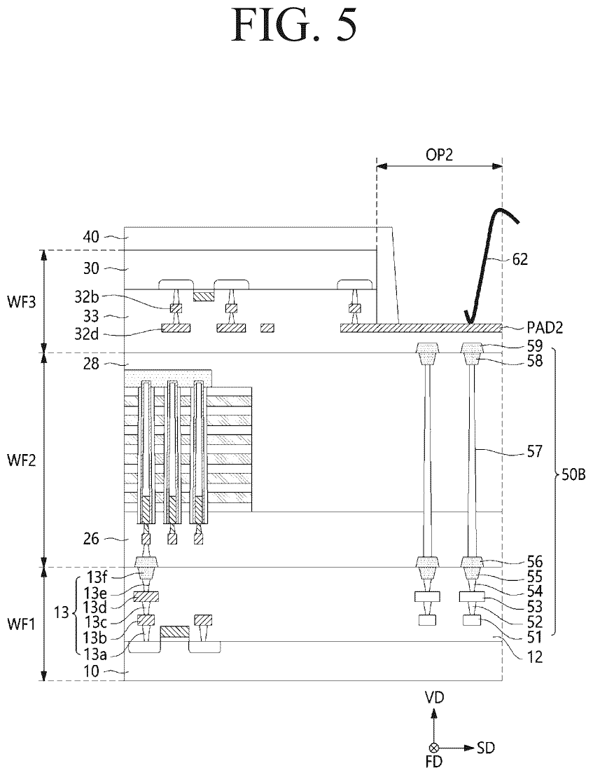

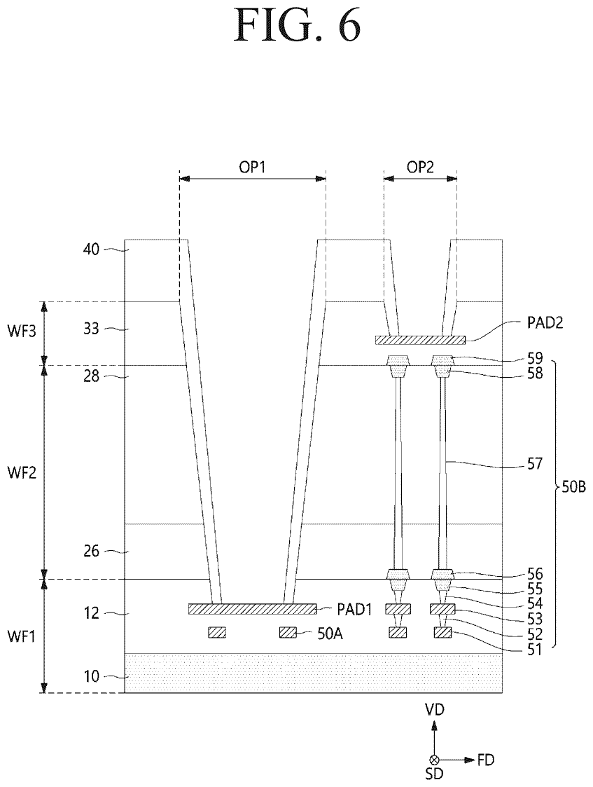

FIG. 4 to FIG. 6 are cross-sectional views illustrating first and second external connection pads of the memory device based on an embodiment of the present disclosure. FIG. 4 is a cross-sectional view taken in the second direction SD through a region including the first external connection pad PAD1, for example, as shown in FIG. 2. FIG. 5 is a cross-sectional view taken in the second direction SD through a region including the second external connection pad PAD2, for example, as shown in FIG. 2. FIG. 6 is a cross-sectional view taken in the first direction FD through a region including the first external connection pad PAD1 and the second external connection pad PAD2, for example, as shown in FIG. 2.

Referring to FIG. 4 and FIG. 6, the first external connection pad PAD1 is disposed in the same layer or level as the second metal layer 13d of the first wafer WF1. The first external connection pad PAD1 may be formed together with the second metal layer 13d during a process of forming the second metal layer 13d. Although FIG. 4 and FIG. 6 illustrate an example where the first external connection pad PAD1 is disposed in the same layer as the second metal layer 13d, the present disclosure is not limited to this example. The first external connection pad PAD1 may be disposed in the same layer as the first metal layer 13b or may be disposed in the same layer as the first bonding pad 13f.

A first open space OP1 that exposes the first external connection pad PAD1 is formed in the third wafer WF3, the second wafer WF2, and the first wafer WF1. The side surface of the third wafer WF3, the side surface of the second wafer WF2 and the side surface of the first insulating layer 12 may be exposed through the first open space OP1.

The top surface of the second substrate 30 of the third wafer WF3, the side surface of the third wafer WF3, the side surface of the second wafer WF2, and the side surface of the first insulating layer 12 that are exposed through the first open space OP1 are covered with a protection layer 40.

A first external connection terminal 61 is connected to the first external connection pad PAD1. The first external connection terminal 61 may be a bonding wire or other electrically conductive device.

The first wafer WF1 includes a first reinforcing member 50A that is disposed below the first external connection pad PAD1. A section or the entirety of the first reinforcing member 50A is disposed below the first external connection pad PAD1 in the vertical direction VD. The first reinforcing member 50A suppresses defects such as cracks from occurring due to stress applied during a process of bonding the first external connection terminal 61 to the first external connection pad PAD1.

The first reinforcing member 50A is disposed in the same layer as the first metal layer 13b in this example. The first reinforcing member 50A may be formed at the same time the first metal layer 13b is formed during a process of forming the first metal layer 13b. Although FIG. 4 and FIG. 6 illustrate an example where the first reinforcing member 50A is disposed in the same layer as the first metal layer 13b, the present disclosure is not limited to this example.

Referring to FIG. 5 and FIG. 6, the second external connection pad PAD2 is disposed at the same layer as the fourth metal layer 32d of the third wafer WF3. The second external connection pad PAD2 may be formed at the same time as the fourth metal layer 32d is formed during a process of forming the fourth metal layer 32d. Although FIG. 5 and FIG. 6 illustrate an example where the second external connection pad PAD2 is disposed at the same layer as the fourth metal layer 32d, the present disclosure is not limited to this example. For example, the second external connection pad PAD2 may be disposed at the same layer as the fifth metal layer 32b or may be disposed at the same layer as the fourth bonding pad 32f (see FIG. 3).

A second open space OP2 that exposes the second external connection pad PAD2 is formed in the third wafer WF3. Because the second open space OP2 is formed in the second substrate 30 and the fourth insulating layer 33 of the third wafer WF3, the second external connection pad PAD2 is exposed.

A side surface of the second substrate 30 and the side surface of the fourth insulating layer 33 are exposed through the second open space OP2. The top surface of the second substrate 30, the side surface of the second substrate 30, and the side surface of the fourth insulating layer 33 that are each exposed through the second open space OP2 are covered with the protection layer 40.

The second external connection pad PAD2 has a smaller measurement than the first external connection pad PAD1 in the first direction FD such as shown in the example of FIG. 6. A second external connection terminal 62 is connected to the second external connection pad PAD2. The second external connection terminal 62 may be a bonding wire or other electrically conductive device.

A second reinforcing member 50B is disposed below the second external connection pad PAD2. The second reinforcing member 50B may be disposed in at least one of the first wafer WF1, the second wafer WF2, and third wafer WF3. A section or the entirety of the second reinforcing member 50B is disposed below the second external connection pad PAD2 in the vertical direction VD. The second reinforcing member 50B suppresses defects such as cracks from occurring due to stress applied during a process of bonding the second external connection terminal 62 to the second external connection pad PAD2.

The second reinforcing member 50B includes a first dummy metal layer 51, a first dummy via 52, a second dummy metal layer 53, a second dummy via 54, a first dummy bonding pad 55, a second dummy bonding pad 56, a dummy through wiring 57, a third dummy bonding pad 58, and a fourth dummy bonding pad 59 in the example of FIG. 5, but the present disclosure is not limited to this example.

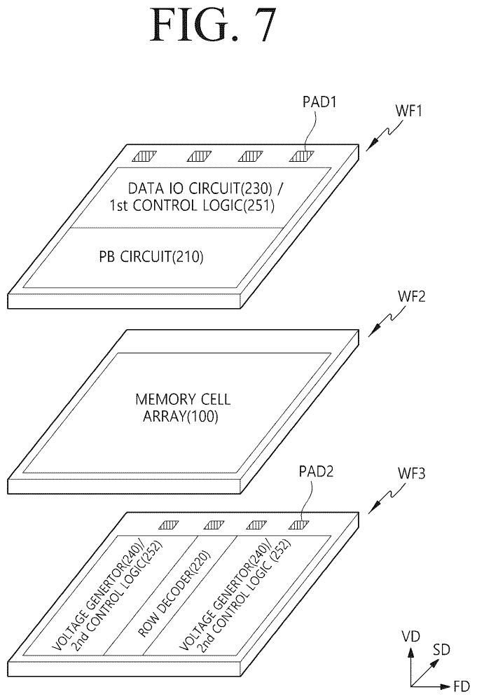

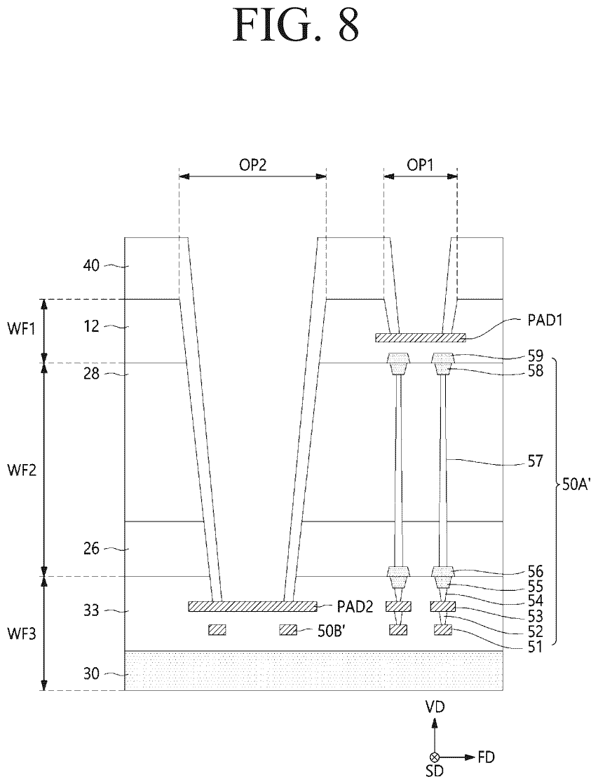

In the embodiment described above with reference to FIG. 2 through FIG. 6, an example where the first wafer WF1 is disposed under the second wafer WF2 in the vertical direction VD, and the third wafer WF3 is disposed on the second wafer WF2 is illustrated. The present disclosure is not limited to this example. The third wafer WF3 may be disposed under the second wafer WF2 in the vertical direction VD, and the first wafer WF1 may be disposed on the second wafer WF2, as described with reference to FIG. 7 and FIG. 8.

FIG. 7 is a diagram illustrating a memory device based on an embodiment of the present disclosure. FIG. 8 is a cross-sectional view illustrating a region including first external connection pads and second external connection pads, for example, as shown in FIG. 7.

Referring to FIG. 7, the second wafer WF2 is stacked on and bonded to the third wafer WF3 in the vertical direction VD. The first wafer WF1 is stacked on and bonded to the second wafer WF2 in the vertical direction VD. The second wafer WF2 is bonded to the top surface of the third wafer WF3 using a wafer-to-wafer bonding method, and the first wafer WF1 may be bonded to the top surface of the second wafer WF2 using a wafer-to-wafer bonding method.

Referring to FIG. 8, the first open space OP1 that exposes the first external connection pad PAD1 is formed in the first wafer WF1. Because the first open space OP1 is formed in the first insulating layer 12 of the first wafer WF1, the first external connection pad PAD1 is exposed.

The side surface of the first insulating layer 12 is exposed through the first open space OP1. The top surface of the first wafer WF1 and the side surface of the first insulating layer 12 that are exposed through the first open space OP1 are covered with the protection layer 40.

A first reinforcing member 50A′ may be disposed below the first external connection pad PAD1.

The first reinforcing member 50A′ is disposed in at least one of the first wafer WF1, the second wafers WF2, and the third wafer WF3. A section or the entirety of the first reinforcing member 50A′ is disposed below the first external connection pad PAD1 in the vertical direction VD.

The first reinforcing member 50A′ includes the first dummy metal layer 51, the first dummy via 52, the second dummy metal layer 53, the second dummy via 54, the first dummy bonding pad 55, the second dummy bonding pad 56, the dummy through wiring 57, the third dummy bonding pad 58, and the fourth dummy bonding pad 59 in the example of FIG. 8, but the present disclosure is not limited to this example.

A second open space OP2 that exposes the second external connection pad PAD2 is formed in the first wafer WF1, the second wafer WF2, and the third wafer WF3. Because the second open space OP2 is formed in the first wafer WF1, the second wafer WF2, and the fourth insulating layer 33 of the third wafer WF3, the second external connection pad PAD2 is exposed.

The side surface of the first wafer WF1, the side surface of the second wafer WF2, and the side surface of the fourth insulating layer 33 may be exposed through the second open space OP2. The top surface of the first wafer WF1, the side surface of the first wafer WF1, the side surface of the second wafer WF2, and the side surface of the fourth insulating layer 33 that are exposed through the second open space OP2 are covered with the protection layer 40.

A second reinforcing member 50B′ is disposed below the second external connection pad PAD2 in the example of FIG. 8. The third wafer WF3 includes the second reinforcing member 50B′. A section or the entirety of the second reinforcing member 50B′ is disposed below the second external connection pad PAD2 in the vertical direction VD.

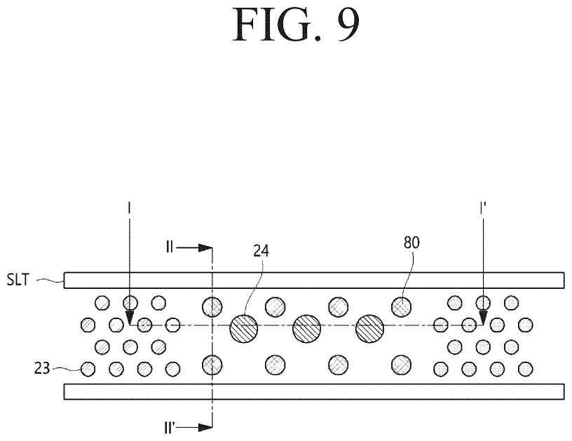

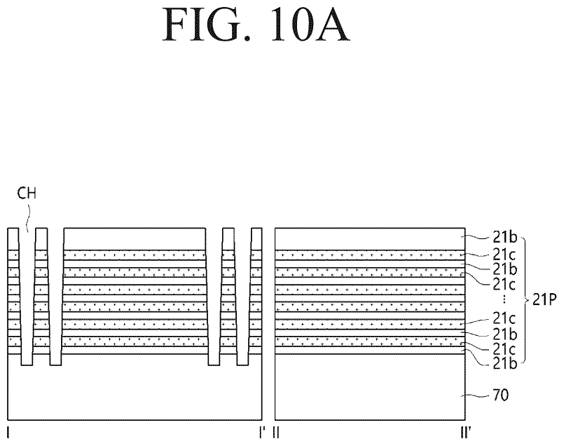

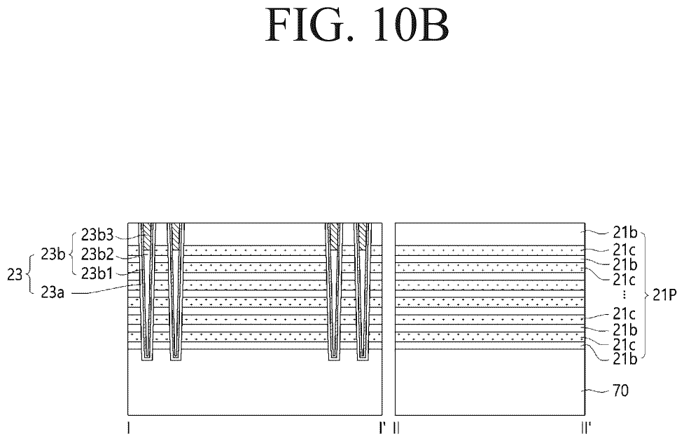

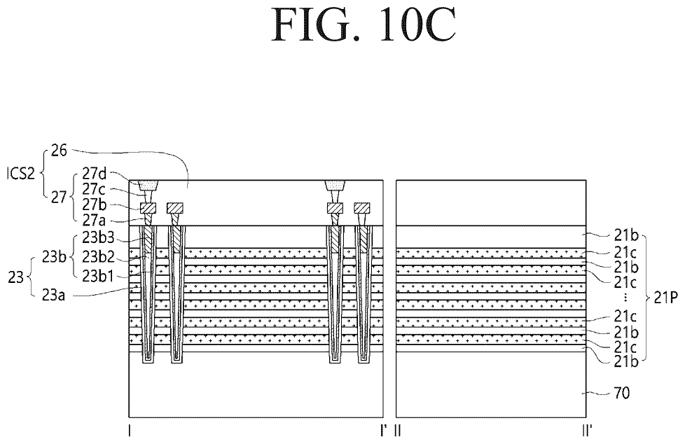

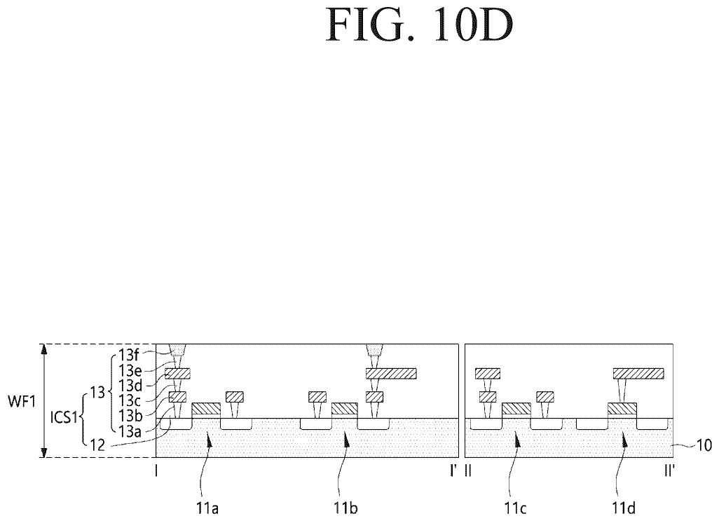

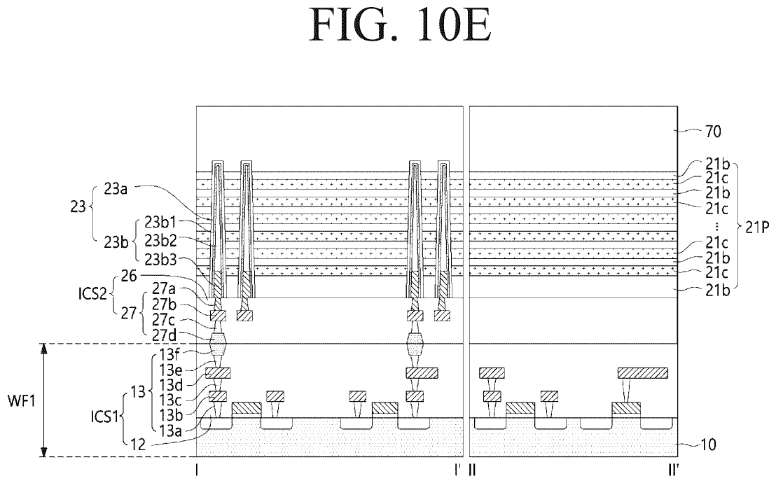

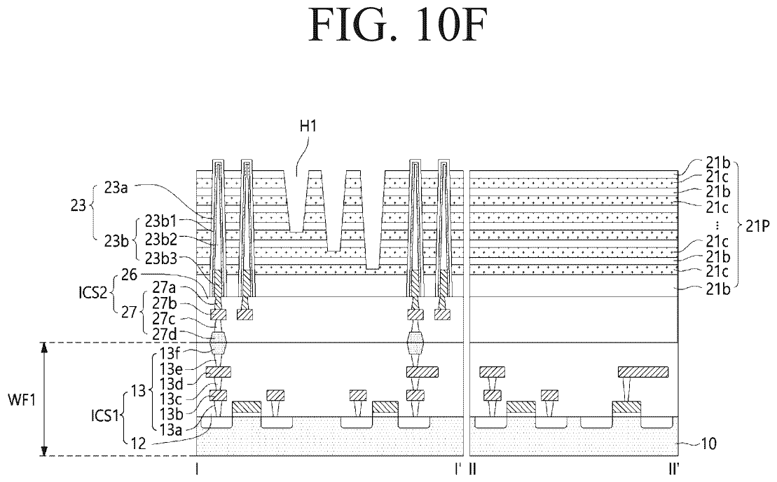

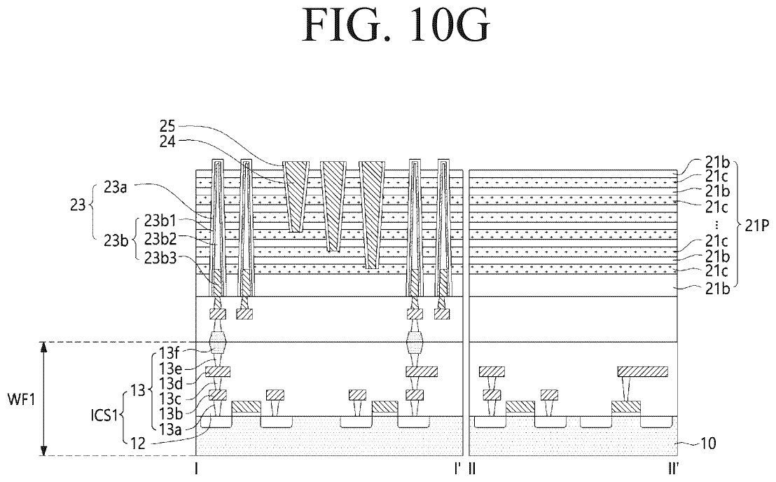

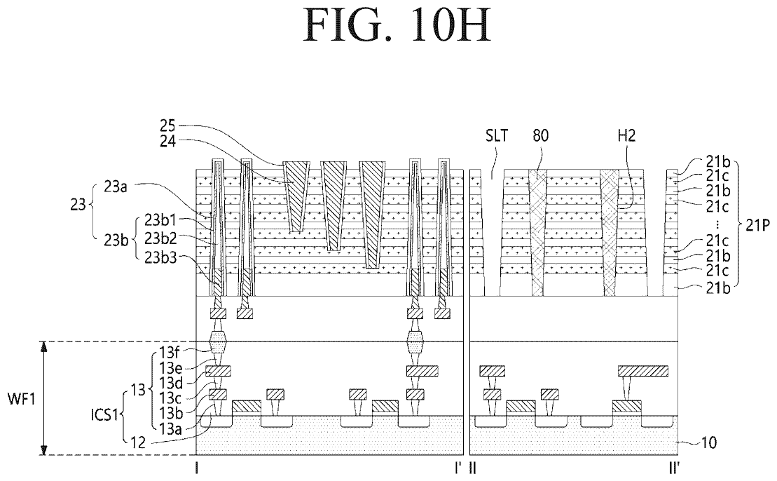

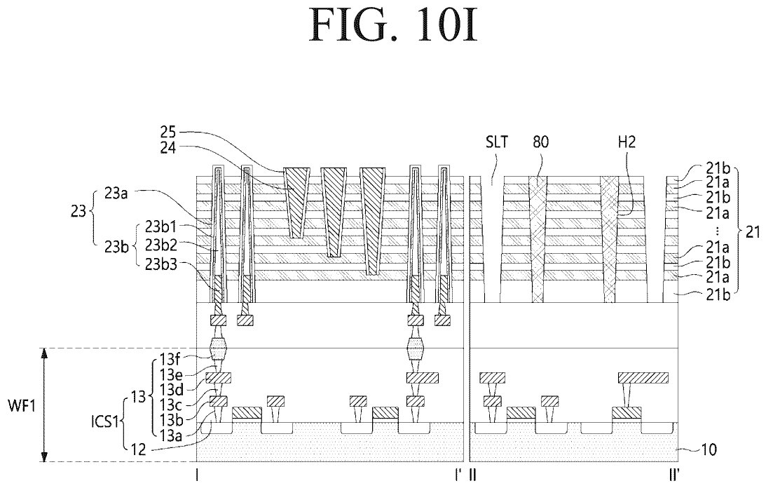

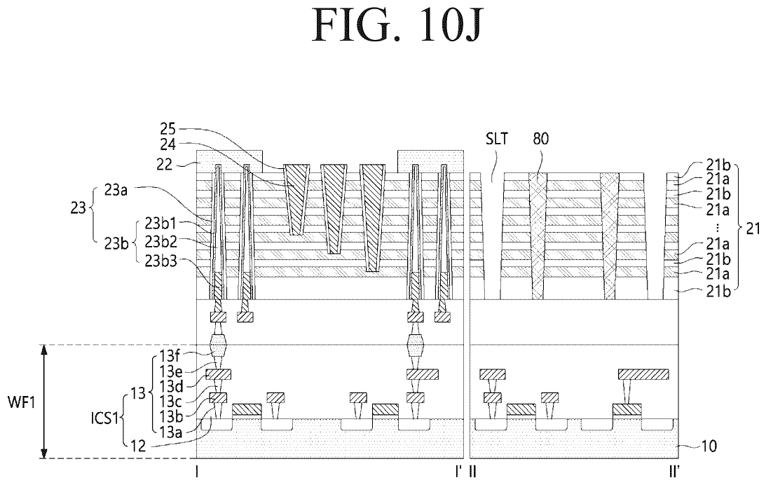

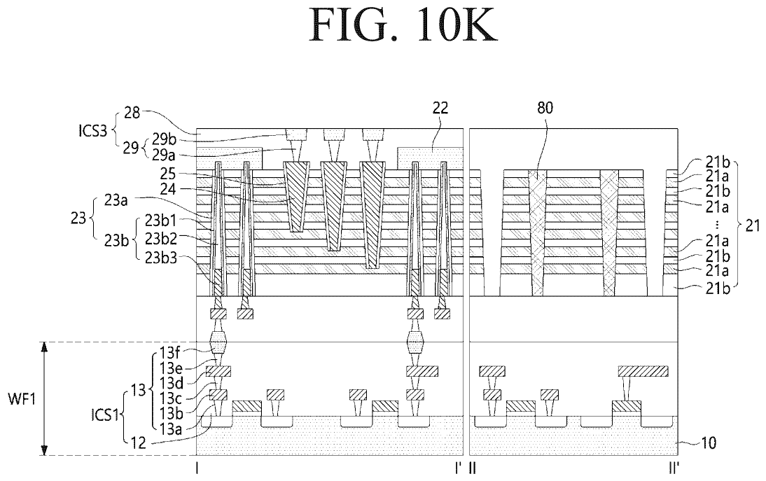

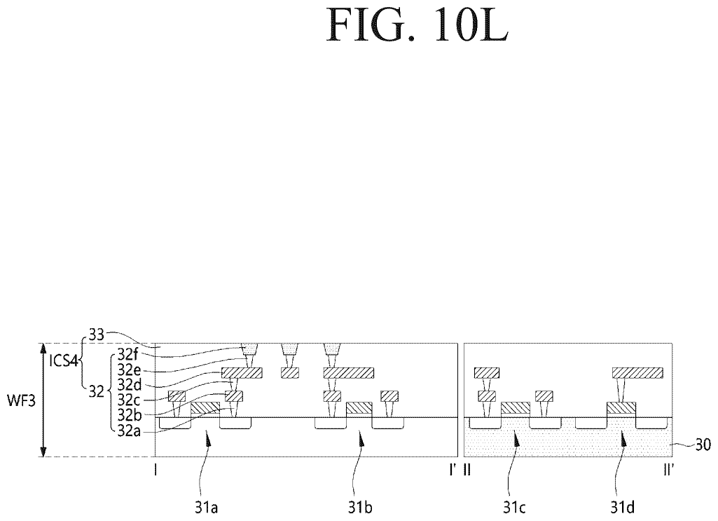

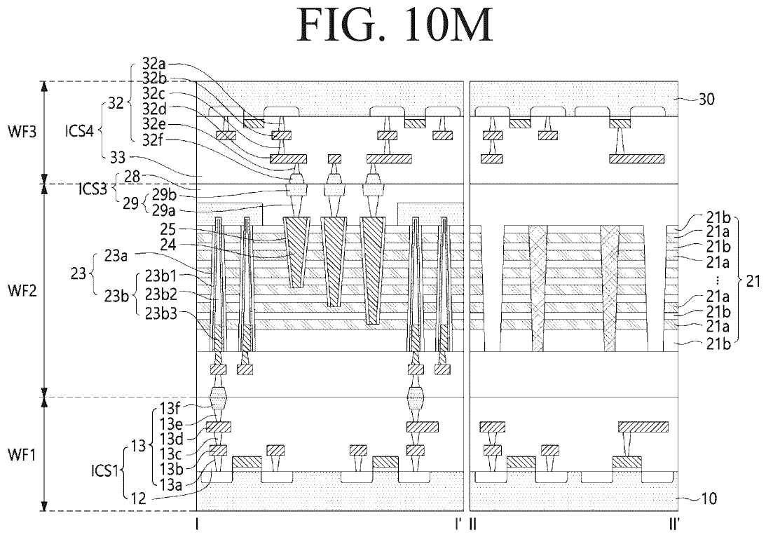

FIG. 9 is a plan view illustrating cell plugs, word line contacts, supports, and slits of a memory device based on an embodiment of the present disclosure. FIG. 10A through FIG. 10M are cross-sectional views illustrating the memory device based on an embodiment of the present disclosure according to a processing sequence.

In each of FIG. 10A to FIG. 10M, a left side represents a cross-section corresponding to the line I-I′ of FIG. 9, and a right side represents a cross section corresponding to the line II-II′ of FIG. 9.

Referring to FIG. 9 and FIG. 10A, a plurality of interlayer insulating layers 21b are alternately stacked with a plurality of sacrificial layers 21c forming a pre-stack 21P. The interlayer insulating layers 21b may include oxide such as silicon oxide. The sacrificial layers 21c may include a material that has a different etch selectivity than the etch selectivity of the interlayer insulating layers 21b, for example, a nitride such as silicon nitride.

Channel holes CH that extend into the sacrificial substrate 70 by passing through the pre-stack 21P are formed. The channel holes CH partially extend into the sacrificial substrate 70.

The channel holes CH are formed by forming, on the pre-stack 21P, a mask pattern with openings that expose different areas predetermined to form the channel holes CH and etching the pre-stack 21P using the mask pattern as an etch mask. The sidewalls of the channel holes CH may have a slope. The width in the first direction FD of the channel hole CH may decrease closer to the sacrificial substrate 70.

Referring to FIG. 9 and FIG. 10B, cell plugs 23 are formed in the channel holes CH.

As described above with reference to FIG. 3, the cell plug 23 includes a memory pattern 23a and a channel structure 23b. The channel structure 23b includes a channel layer 23b1, a core pillar 23b2, and a capping pattern 23b3. Because the channel holes CH partially extend into the sacrificial substrate 70, the cell plugs 23 protrude downward through the bottom surface of the pre-stack 21P.

Referring to FIG. 9 and FIG. 10C, a second interconnection layer ICS2 is formed on the pre-stack 21P.

The second interconnection layer ICS2 includes a second insulating layer 26 and a plurality of second connection structures 27. The second connection structure 27 includes a second bonding pad 27d, a third metal layer 27b, and second vias 27a and 27c.

Referring to FIG. 9 and FIG. 10D, a first wafer WF1 is formed.

The first wafer WF1 includes a first substrate 10, a plurality of first circuit elements 11a, 11b, 11c, and 11d that are formed in the first substrate 10, and a first interconnection layer ICS1.

The first circuit elements 11a, 11b, 11c, and 11d are used to configure the page buffer circuit 210, the data input/output circuit 230, and the first control logic 251. The first interconnection layer ICS1 includes a plurality of first connection structures 13 and a first insulating layer 12. The first connection structure 13 includes a first metal layer 13b, a second metal layer 13d, a first bonding pad 13f, and first vias 13a, 13c, and 13e.

Referring to FIG. 9 and FIG. 10E, the second wafer WF2 is bonded to the first wafer WF1.

After the sacrificial substrate 70 and layers formed on the sacrificial substrate 70 are turned upside-down or flipped over in the vertical direction VD, the second interconnection layer ICS2 of the second wafer WF2 is bonded to the first interconnection layer ICS1 of the first wafer WF1.

Referring to FIG. 9 and FIG. 10F, the sacrificial substrate 70 is removed. As the sacrificial substrate 70 is removed, the protrusions of the cell plugs 23 are exposed.

A plurality of first holes H1, each of which extends into a corresponding sacrificial layer 21c by extending through the pre-stack 21P exposed by removal of the sacrificial substrate 70, are formed.

The first holes H1 are formed by forming, on the pre-stack 21P, a mask pattern with openings that expose areas predetermined to form the first holes H1 and etching the pre-stack 21P using the mask pattern as an etch mask. The sidewalls of the first holes H1 may have a slope. The width, in the first direction FD, of the first hole H1 may decrease closer to the first wafer WF1.

Referring to FIG. 9 and FIG. 10G, insulating sidewalls 25 that surround the side surfaces of the pre-stack 21P adjacent to the first holes H1 are formed, and word line contacts 24 are formed within the insulating sidewalls 25.

Referring to FIG. 9 and FIG. 10H, supports 80 and slits SLT are formed.

Second holes H2 are formed by forming, on the pre-stack 21P, a mask pattern with openings that expose areas predetermined to form the second holes H2 and etching the pre-stack 21P using the mask pattern as an etching mask. The supports 80 is formed by filling the second holes H2 with an insulating material.

The sidewalls of the second holes H2 may have a slope. The width, in the first direction FD, of the second hole H2 may decrease closer to the first wafer WF1. The width, in the first direction FD, of the support 80 may decrease closer to the first wafer WF1.

The slits SLT are formed by forming, on the pre-stack 21P, a mask pattern with openings that expose areas predetermined to form the slits SLT and etching the pre-stack 21P using the mask pattern as an etch mask. The sidewalls of the slit SLT may have a slope. The width, in the first direction FD, of the slit SLT may decrease closer to the first wafer WF1.

Referring to FIG. 9 and FIG. 10I, the plurality of sacrificial layers 21c are replaced with gate electrode layers 21a. Thus, a gate stack 21 having a structure in which the gate electrode layers 21a are alternately stacked with the plurality of interlayer insulating layers 21b is formed.

Referring to FIG. 9 and FIG. 10J, the memory pattern 23a that protrudes above the top surface of the gate stack 21 is removed. As a result, the channel layer 23b1 is exposed.

A source plate 22 that covers the cell plugs 23 is formed on the gate stack 21. The source plate 22 contacts the channel layers 23b1 of the cell plugs 23.

Referring to FIG. 9 and FIG. 10K, a third interconnection layer ICS3 may be formed on the gate stack 21.

The third interconnection layer ICS3 includes a third insulating layer 28 and a plurality of third connection structures 29. The third connection structure 29 includes a third bonding pad 29b and a third via 29a. The third insulating layer 28 covers the gate stack 21, the source plate 22, and the plurality of third connection structures 29. The top surface of the third bonding pad 29b is exposed adjacent to the top surface of the third insulating layer 28.

Referring to FIG. 9 and FIG. 10L, a third wafer WF3 is formed.

The third wafer WF3 includes a second substrate 30, a plurality of second circuit elements 31a, 31b, 31c, and 31d that are formed on the second substrate 30, and a fourth interconnection layer ICS4.

The second circuit elements 31a, 31b, 31c, and 31d are used to configure the row decoder 220, the voltage generator 240, and the second control logic 252. The fourth interconnection layer ICS4 includes a plurality of fourth connection structures 32 and a fourth insulating layer 33. The fourth connection structure 32 includes a fourth metal layer 32d, a fifth metal layer 32b, a fourth bonding pad 32f, and fourth vias 32a, 32c, and 32e. The top surface of the fourth bonding pad 32f is exposed adjacent to the top surface of the fourth insulating layer 33.

Referring to FIG. 9 and FIG. 10M, the third wafer WF3 is bonded to the second wafer WF2.

After the third wafer WF3 is turned upside-down or flipped over in the vertical direction VD, the fourth interconnection layer ICS4 of the third wafer WF3 is bonded to the third interconnection layer ICS3 of the second wafer WF2.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

What is claimed is:

1. A memory device comprising:
a first wafer including a page buffer circuit and a data input/output circuit connected to the page buffer circuit;
a second wafer having a first surface bonded to the first wafer and a second surface opposite to the first surface in a first direction and including a plurality of word lines, a memory cell array, and a plurality of bit lines connected to the page buffer circuit; and
a third wafer bonded to the second surface of the second wafer and including a row decoder connected to the plurality of word lines and a voltage generator that provides an operating voltage to the row decoder.

2. The memory device according to claim 1, further comprising:
first control logic configured to control the page buffer circuit and the data input/output circuit; and
second control logic configured to control the row decoder and the voltage generator,
wherein the first control logic is included in the first wafer, and the second control logic is included in the third wafer.

3. The memory device according to claim 1,
wherein the first wafer further includes, on a surface bonded to the first surface of the second wafer, a first bonding pad connected to the page buffer circuit;
wherein the second wafer further includes, on the first surface, a second bonding pad connected to one of the plurality of bit lines; and
wherein the first bonding pad is electrically connected to the second bonding pad.

4. The memory device according to claim 1,
wherein the second wafer further includes, on the second surface, a first bonding pad connected to one of the plurality of word lines;
wherein the third wafer further includes, on a surface bonded to the second surface of the second wafer, a second bonding pad connected to the row decoder; and
wherein the first bonding pad is electrically connected to the second bonding pad.

5. The memory device according to claim 1, wherein the memory cell array, the row decoder, and the page buffer circuit are at least partially aligned in the first direction.

6. A memory device comprising:
a first wafer including a page buffer circuit, a data input/output circuit, and a plurality of first external connection pads;
a second wafer having a first surface bonded to the first wafer and a second surface opposite to the first surface in a first direction and including a plurality of bit lines, a plurality of word lines, and a memory cell array; and
a third wafer bonded to the second surface of the second wafer and including a row decoder, a voltage generator, and a plurality of second external connection pads.

7. The memory device according to claim 6, wherein
one of the page buffer circuit, the data input/output circuit, and a first control logic is connected to one of the plurality of first external connection pads; and
one of the row decoder, the voltage generator, and a second control logic is connected to one of the plurality of second external connection pads.

8. The memory device according to claim 6, wherein the plurality of first external connection pads comprises a data pad.

9. The memory device according to claim 6, wherein the plurality of second external connection pads comprises an analog signal pad.

10. The memory device according to claim 6, wherein the plurality of first external connection pads includes at least one of a power pad and a ground pad, and the plurality of second external connection pads includes at least one of a power pad and a ground pad.

11. The memory device according to claim 6, further comprising:
a first open space formed in the first wafer, the second wafer, and the third wafer such that the first external connection pad is exposed; and
a second open space formed in the third wafer such that the second external connection pad is exposed.

12. The memory device according to claim 6, wherein a measurement of the first external connection pad in a second direction is larger than a measurement of the second external connection pad in the second direction.

13. The memory device according to claim 6, further comprising:
a first reinforcing member included in the first wafer and aligned with the first external connection pad in the first direction; and
a second reinforcing member included in at least one of the first wafer, the second wafer, and the third wafer and aligned with the second external connection pad in the first direction.

14. The memory device according to claim 6, further comprising:
a first open space formed in the first wafer such that the first external connection pad is exposed; and
a second open space formed in the first wafer, the second wafer, and the third wafer such that the second external connection pad is exposed.

15. The memory device according to claim 6, wherein a measurement of the second external connection pad in a second direction is larger than a measurement of the first external connection pad in the second direction.

16. The memory device according to claim 6, further comprising:
a first reinforcing member included in at least one of the first wafer, the second wafer, and the third wafer and aligned with the first external connection pad in the first direction; and
a second reinforcing member included in the third wafer and aligned with the second external connection pad in the first direction.

17. A memory device comprising:
a wafer having a first surface opposite to a second surface in a first direction;
a first bonding pad disposed on the first surface;
a second bonding pad disposed on the second surface;
a gate stack disposed between the first surface and the second surface and including a plurality of gate electrode layers alternately stacked with a plurality of interlayer insulating layers in the first direction;
a cell plug passing through the gate stack in the first direction;
a bit line connected to the cell plug; and
a word line contact extending to a gate electrode layer through the gate stack in the first direction and having a first end contacting the gate electrode layer and a second end opposite to the first end in the first direction;
wherein the bit line is disposed between the first surface and the gate stack; and
wherein the second end of the word line contact is disposed between the second surface and the gate stack.

18. The memory device according to claim 17, further comprising:
a first via connecting the bit line and the first bonding pad; and
a second via connecting the second end of the word line contact and the second bonding pad.

19. The memory device according to claim 17, wherein the word line contact has a tapered shape having a width that decreases closer to the first surface.

20. The memory device according to claim 17, wherein the cell plug has a reverse tapered shape having a width that increases closer to the first surface.

21. The memory device according to claim 17, further comprising:
a support passing through the gate stack,
wherein the support has a tapered shape having a width that decreases closer to the first surface.

22. The memory device according to claim 17, further comprising:
a slit dividing the gate stack,
wherein the slit has a tapered shape having a width that decreases closer to the first surface.

23. A method for manufacturing a memory device, the method comprising:
forming, on a sacrificial substrate, a pre-stack comprising a plurality of sacrificial layers alternately stacked with a plurality of interlayer insulating layers;
forming a cell plug passing through the pre-stack;
forming, on the pre-stack, a first interconnection layer including a bit line connected to the cell plug and a first bonding pad connected to the bit line;
forming a first peripheral wafer having a second interconnection layer including a second bonding pad;
electrically connecting the first bonding pad to the second bonding pad by bonding the first interconnection layer to the second interconnection layer;
removing the sacrificial substrate to expose a surface of the pre-stack;
forming a word line contact that extends between the surface of the pre-stack and a sacrificial layer among the plurality of sacrificial layers;
forming a gate stack by replacing the plurality of sacrificial layers with a plurality of gate electrode layers;
forming, on the gate stack, a third interconnection layer including a third bonding pad connected to the word line contact;
forming a second peripheral wafer having a fourth interconnection layer including a fourth bonding pad; and
electrically connecting the fourth bonding pad to the third bonding pad by bonding the fourth interconnection layer to the third interconnection layer.

24. The method according to claim 23, wherein
the first peripheral wafer further includes a page buffer circuit and a data input/output circuit, and
the second peripheral wafer further includes a row decoder and a voltage generator.

25. The method according to claim 23, further comprising, between removing the sacrificial substrate, forming a slit dividing the pre-stack and replacing the plurality of sacrificial layers with the plurality of gate electrode layers.

26. The method according to claim 23, further comprising, between removing the sacrificial substrate and replacing the plurality of sacrificial layers with the plurality of gate electrode layers, forming a support that passes through the pre-stack.

27. The method according to claim 23, further comprising prior to forming the third interconnection layer, forming, on the gate stack, a source plate connected to the cell plug.

28. A memory device comprising:
a first wafer including a first peripheral circuit;
a second wafer having a first surface bonded to the first wafer and a second surface and including a plurality of word lines, a memory cell array, and a plurality of bit lines connected to the first peripheral circuit through the first surface of the second wafer; and
a third wafer bonded to the second surface of the second wafer and including a second peripheral circuit connected to the plurality of word lines through the second surface;
wherein the plurality of bit lines are connected to the first peripheral circuit without passing through the third wafer; and
wherein the plurality of word lines are connected to the second peripheral circuit without passing through the first wafer.
